(19) United States
(12) Patent Application Publication
(10) Pub. No.: US 2026/0113175 A1
(43) Pub. Date: Apr. 23, 2026

(54) Synchronization Detection System, Synchronization Detection Device and Synchronization Detection Method in Oscillator System

(71) Applicant: NTT, Inc., Tokyo (JP)

(72) Inventors: Yasuhiro Yamada, Musashino-shi, Tokyo (JP); Kensuke Inaba, Musashino-shi, Tokyo (JP); Hiroki Takesue, Musashino-shi, Tokyo (JP); Takahiro Inagaki, Musashino-shi, Tokyo (JP); Toshimori Honjo, Musashino-shi, Tokyo (JP); Takuya Ikuta, Musashino-shi, Tokyo (JP); Yuya Yonezu, Musashino-shi, Tokyo (JP)

(21) Appl. No.: 19/118,201

(22) PCT Filed: Oct. 14, 2022
(86) PCT No.: PCT/JP2022/038406

§ 371 Date: Apr. 3, 2025

(51) Int. Cl. H04L 7/033; H03L 7/099

(52) U.S. Cl. CPC H04L 7/033; H03L 7/099

(57) ABSTRACT

A synchronization detection device includes: a pseudo-vorticity matrix calculation unit that inputs time evolution information of phases from an oscillator system including a finite number of oscillators and calculates a matrix having elements each of which is a discretized value of a phase difference obtained by two of the oscillators by time evolution; a synchronization graph generation unit that generates a synchronization graph that visualizes two-point synchronization with a graph representation; a partial synchronization set detection unit that detects a plurality of subsets of the oscillators having no common portion and partially synchronized in a set of a finite number of the oscillators in the synchronization graph; and a synchronization index calculation unit that generates an index characterizing partial synchronization of the oscillator system using a calculation result calculated by the pseudo-vorticity matrix calculation unit and a partial synchronization set detected by the partial synchronization set detection unit.

### TECHNICAL FIELD

The present disclosure relates to a synchronization detection system, a synchronization detection device and a synchronization detection method for detecting synchronization in an oscillator system, and more particularly to a technique for identifying a group of oscillators that are partially synchronized from change over time of each oscillator.

### BACKGROUND ART

Oscillator systems are known as physical systems that can be described by a periodically changing wave phase θ, such as electromagnetic waves, the position and momentum of a pendulum, alternating current flowing through a power grid, the concentration of chemical species in a chemical reaction, the firing signals of neurons in the brain, and the contraction patterns of cardiac muscle. Moreover, oscillators can be artificially created using electrical circuits or optical circuits, and their motion can be simulated by numerical calculations.

In a coupled oscillator system in which a plurality of oscillators are linked, even if the oscillators initially have different phases, the interaction between the oscillators due to the coupling eventually leads to a synchronization phenomenon in which the oscillators oscillate with the same phase. When there are n oscillators in a system and the phase of the j-th oscillator at a certain time t is expressed as θⱼ(t), the degree of synchronization can be quantitatively expressed by an order parameter r(t) defined by the following (1).

$$[ Math . 1 ]$$

$$r ( t ) = \vert \frac{1}{n} {\sum }_{j = 1}^{n} {e}^{i {θ}_{j} ( t )} \vert \qquad Formula ( 1 )$$

In Formula (1), r(t)=1 indicates a completely synchronous state, and r(t)=0 indicates a completely asynchronous state. Familiar examples of synchronization phenomena include the collective lighting of fireflies and the beating of the heart.

Incidentally, in synchronization, partial synchronization, in which only some oscillators are synchronized, is also observed, rather than the entire system being synchronized (complete synchronization). Partial synchronization has been observed in, for example, power grid blackouts, ventricular fibrillation of the heart, and the electroencephalogram of marine mammals during hemispheric sleep. The occurrence of partial synchronization has also been confirmed in artificial oscillator systems simulated by numerical calculations and created using electrical circuits, etc.

However, non-uniform partial synchronization cannot be adequately detected using the order parameter shown in Formula (1). In contrast, NPL 1 describes an index that works well under the assumption that oscillators exist in n-dimensional Euclidean space. In addition, NPL 2 describes a method of examining partial synchronization for a predetermined subset of oscillators under the assumption that a group of oscillators that are consistent with the symmetry of a graph is partially synchronized for an oscillator system on a graph.

### CITATION LIST

### Non Patent Literature

[NPL 1] F. P. Kemeth et al., “A classification scheme for chimera states” Chaos 26, 094815 (2016).
[NPL 2] L. M. Pecora et al., “Cluster synchronization and isolated desynchronization in complex networks with symmetries,” Nat Commun. 5:4079 (2014).
[NPL 3] A. Lucas, “Ising formulations of many NP problems,” Front. in Phys. 2, 1 (2014).

### SUMMARY OF INVENTION

However, the indicators and methods provided by the above known techniques are highly dependent on assumptions derived from the space in which the oscillators exist and the shape of the graph. Realistic oscillator systems and partial synchronization that actually occurs may not satisfy these assumptions. For this reason, with the techniques described in NPL 1 and NPL 2, it is difficult to stably detect partial synchronization that actually occurs using the results of an arbitrary experimental system or numerical calculations. Incidentally, physically identifying a group of partially synchronized oscillators in a finite oscillator system is mathematically equivalent to introducing subsets (equivalence class) that appropriately divides the entire set of oscillators, when the entire set of oscillators is considered as a countable set. However, a specific method for introducing the appropriate subsets that corresponds to the partial synchronization that actually occurs is not obvious. Furthermore, in any finite oscillator system, even if the oscillators are synchronized, the phase of the entire system will not be completely the same value, and some oscillators may follow with a delayed phase.

The present disclosure has been made in consideration of the above points, and relates to a synchronization detection system, a synchronization detection device, and a synchronization detection method that extend the concept of synchronization to synchronization that allows for phase delay, and that are capable of identifying and detecting subsets corresponding to a group of partially synchronized oscillators using the time evolution results of the phase of any finite number of oscillators that can be observed through experiments or numerical calculations.

In order to achieve the above object, according to one aspect of the present disclosure, there is provided a synchronization detection system including: a phase information output unit that outputs time evolution information of phases from an oscillator system including a finite number of oscillators; a pseudo-vorticity matrix calculation unit that calculates a matrix having elements each of which is a discretized value of a phase difference obtained by two of the oscillators by time evolution; a synchronization graph generation unit that generates a synchronization graph that visualizes two-point synchronization with a graph representation; a partial synchronization set detection unit that detects a plurality of subsets of the oscillators that have no common portion and are partially synchronized in a set of a finite number of the oscillators in the synchronization graph generated by the synchronization graph generation unit; and a synchronization index calculation unit that generates an index characterizing partial synchronization of the oscillator system using a calculation result calculated by the pseudo-vorticity matrix calculation unit and a partial synchronization set detected by the partial synchronization set detection unit.

According to another aspect of the present disclosure, there is provided a synchronization detection device including: a pseudo-vorticity matrix calculation unit that inputs time evolution information of phases from an oscillator system including a finite number of oscillators and calculates a matrix having elements each of which is a discretized value of a phase difference obtained by two of the oscillators by time evolution; a synchronization graph generation unit that generates a synchronization graph that visualizes two-point synchronization with a graph representation; a partial synchronization set detection unit that detects a plurality of subsets of the oscillators that have no common portion and are partially synchronized in a set of a finite number of the oscillators in the synchronization graph generated by the synchronization graph generation unit; and a synchronization index calculation unit that generates an index characterizing partial synchronization of the oscillator system using a calculation result calculated by the pseudo-vorticity matrix calculation unit and a partial synchronization set detected by the partial synchronization set detection unit.

According to still another aspect of the present disclosure, there is provided a synchronization detection method including: a pseudo-vorticity matrix calculation step of inputting time evolution information of phases from an oscillator system including a finite number of oscillators and calculating a matrix having elements each of which is a discretized value of a phase difference obtained by two of the oscillators by time evolution; a synchronization graph generation step of generating a synchronization graph that visualizes two-point synchronization with a graph representation; a partial synchronization set detection step of detecting a plurality of subsets of the oscillators that have no common portion and are partially synchronized in a set of a finite number of the oscillators in the synchronization graph generated in the synchronization graph generation step; and a synchronization index calculation step of generating an index characterizing partial synchronization of the oscillator system using a calculation result calculated in the pseudo-vorticity matrix calculation step and a partial synchronization set detected in the partial synchronization set detection step.

According to the above-described aspects, it is possible to extend the concept of synchronization to synchronization that allows for phase delay, and to identify and detect a subset corresponding to a group of partially synchronized oscillators using the time evolution results of the phase of any finite number of oscillators that can be observed through experiments or numerical calculations.

### BRIEF DESCRIPTION OF DRAWINGS

FIG. 1 is a diagram for describing a synchronization detection device according to an embodiment of the present disclosure.

FIG. 2 is a flowchart for describing a synchronization detection method performed in the synchronization detection device illustrated in FIG. 1.

FIGS. 3(a), 3(b), and 3(c) are schematic diagrams illustrating processes performed after solving a maximum clique problem.

FIGS. 4(a) and 4(b) are both diagrams illustrating the results of numerical calculations simulating the time evolution of an oscillator system in which artificial neurons following the Fitzhugh-Nagumo model are coupled in a small-world network.

### DESCRIPTION OF EMBODIMENTS

### Overview

First, before describing embodiments of the present disclosure, an overview of the present disclosure will be described.

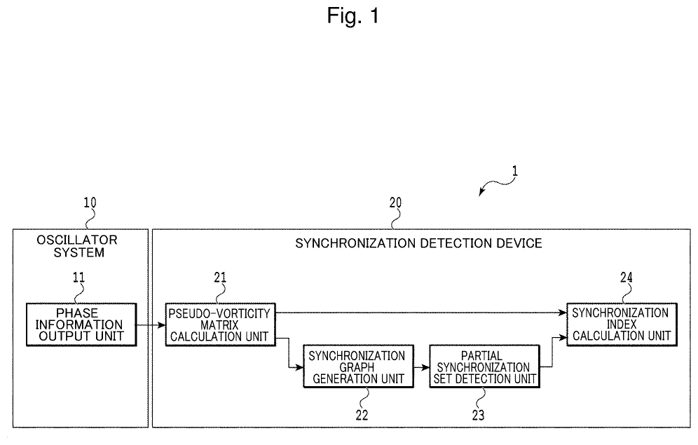

An object of the present disclosure is to extend the concept of synchronization to one that allows for phase delay, and to take, as an input, information of change over time in phases of a finite number of oscillators obtained through experiments or numerical calculations, and to identify and detect a group of oscillators that are partially synchronized within an oscillator system. In order to achieve this object, the inventors of the present disclosure disclose a synchronization detection device illustrated in FIG. 1 as one embodiment. This synchronization detection device is configured to implement a synchronization detection method of the present disclosure. The synchronization detection device and synchronization detection method of the embodiment can detect partial synchronization of any finite oscillator system, and combines a topological perspective with graph theory and functions stably even when a small amount of noise is included in an information phase output.

### Embodiment

An embodiment of the present disclosure will be described below.

FIG. 1 is a view for describing a synchronization detection system according to an embodiment of the present disclosure. A synchronization detection system 1 of the present embodiment includes an oscillator system 10 and a synchronization detection device 20. The synchronization detection device 20 is in the form of an electronic computer, and this electronic computer can be a computer that executes a program for a synchronization detection process to be described below, or can be a computer equipped with a dedicated circuit that executes the above process.

The oscillator system 10 is a finite oscillator system and includes a phase information output unit 11. The phase information output unit 11 outputs numerical data θⱼ(t) representing the change over time in the phase information from the experimental results and numerical calculation results of the oscillator system 10. Specifically, the numerical data θⱼ(t) is information of change over time in phase obtained from the output result of an oscillator system in a living body, the output result of an engineered oscillator system, the experimental result of a chemical reaction, the output signal of an electrical circuit, the output signal of an optical circuit, and the output result of a numerical calculation, or information of change over time in phase obtained by processing the results.

The phase can be expressed as a complex number. Therefore, information of change over time in phase can be expressed as the argument θ(t)=arg (ξ(t)) of a complex number from time series data ξ(t) of a complex number having two degrees of freedom of real numbers.

In the output results of numerical calculations, etc., it is sometimes possible to output time series data u(t) and v(t) for two real variables that constitute one oscillator. In this case, as an embodiment for obtaining time series data of a complex number, ξ(t)=u(t)+iv(t) or ξ(t)=\dot{u}(t)+\dot{i}\dot{v}(t) using the time derivatives \dot{u}(t) and \dot{v}(t) of each piece of time series data can be used.

On the other hand, in the case of time series data obtained in an experiment, such as the output results of electroencephalogram (EEG) signals, there are cases where only one real number of time series data u(t) can be obtained as time series data corresponding to one oscillator. In such a case, as one embodiment, an analytic signal obtained from u(t) (a complex function ξ(t)=ũ(t)+iũ(t) obtained by expanding the real function ũ(t) obtained by performing the Hilbert transform on u(t) so that it becomes analytical on the upper half of the complex plane) can be used.

The synchronization detection device 20 includes: a pseudo-vorticity matrix calculation unit 21 that inputs time evolution information of a phase from an oscillator system 10 including a finite number of oscillators and calculates a matrix having elements each of which is a discretized value of a phase difference obtained by two of the oscillators by time evolution; a synchronization graph generation unit 22 that generates a synchronization graph that visualizes two-point synchronization with a graph representation; a partial synchronization set detection unit 23 that detects subsets of the oscillators that are partially synchronized from the synchronization graph; and a synchronization index calculation unit 24 that generates an index characterizing partial synchronization of the oscillator system using a calculation result calculated by the pseudo-vorticity matrix calculation unit 21 and a subset detected by the partial synchronization set detection unit 23.

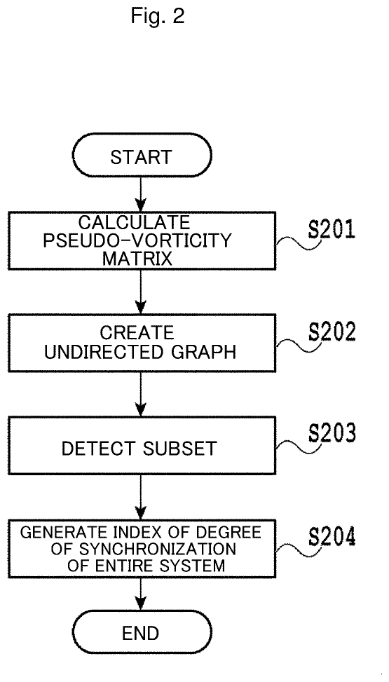

FIG. 2 is a flowchart showing a synchronization detection process executed in the synchronization detection device 20 illustrated in FIG. 1. The synchronization detection process executed in the synchronization detection device 20 will be described in detail below with reference to FIGS. 1 and 2.

The pseudo-vorticity matrix calculation unit 21 calculates a pseudo-vorticity matrix on the basis of the information of change over time in phase output by the phase information output unit 11 (step S201 in FIG. 2). That is, the pseudo-vorticity matrix calculation unit 21 calculates an n-row, n-column skew-symmetric integer matrix I(t, t′) having Iᵢⱼ(t, t′) defined by the following Formula (2) as its (i, j) element, from the information of change over time in phases of the n oscillators output by the phase information output unit 11 of the oscillator system 10.

$$[ Math . 2 ]$$

$${I}_{ij} ( t , {t}^{′} ) ≡ \frac{1}{2 π} [ {\int }_{t}^{{t}^{′}} \frac{d {θ}_{j} ( t )}{dt} dt + {\int }_{{t}^{′}}^{t} \frac{d {θ}_{i} ( t )}{dt} dt + Arg ( {e}^{i ( {θ}_{j} ( t ) - {θ}_{i} ( t )} ) + Arg ( {e}^{i ( {θ}_{j} ( {t}^{′} ) - {θ}_{i} ( {t}^{′} )} ) ] \qquad Formula ( 2 )$$

In Formula (2), n is the number of oscillators included in the system, θᵢ(t) and θⱼ(t) are the phases of two oscillators i and j at time t, and Arg(z) is the principal value of the argument of complex number z, ranging from −π to π. The calculated Iᵢⱼ(t, t′) represents a time series change in the phase output by the phase information output unit 11 from time t to time t′. Furthermore, if the phase of each oscillator is continuous over time, the value of Iᵢⱼ(t, t′) will be an integer value, and this integer value represents the strength of the virtual topological defect (pseudo-vorticity) between oscillator i and oscillator j. For this reason, I(t, t′) will hereinafter be referred to as the “pseudo-vorticity matrix.”

When the change over time of the phases of the two oscillators is not synchronized, a defect is inevitably generated between the two oscillators. Therefore, pseudo-vorticity is an index of the degree of asynchrony in two-point synchronization. Furthermore, if there is phase disturbance or delay within the measurement time, the pseudo-vorticity, which takes a discrete integer value, will not change depending on the degree of the disturbance or delay. For this reason, the pseudo-vorticity matrix calculated by the pseudo-vorticity matrix calculation unit 21 does not change even if the information output by the phase information output unit 11 includes a small amount of noise or includes a small phase delay in synchronization. This makes it possible to extend the concept of synchronization to one that allows for phase delay.

Here, the measurement times t and t′, which can be set arbitrarily, determine the minimum frequency difference at which asynchrony can be detected. If it is desired to detect asynchrony having a frequency difference of δf₀ or more, it is necessary to satisfy |t−t′|δf₀>>1. On the other hand, if it is desired to determine synchronization at a certain moment, it is better to set the measurement time interval |t−t′|δf₀<<1 short. Therefore, the value of the measurement time interval Δt≡|t−t′| is a quantity that determines the frequency resolution and time resolution, which are inversely related.

In addition, when the phase difference obtained by two oscillators by time evolution is ΔΦᵢⱼ(t,t′)≡θⱼ(t′)−θⱼ(t)−θᵢ(t′)+θᵢ(t), Iᵢⱼ(t,t′) and ΔΦᵢⱼ(t,t′) satisfy the relationship of the following Formula (3).

$$[ Math . 3 ]$$

$$⌊ \frac{Δ {Φ}_{ij} ( t , {t}^{′} )}{2 π} ⌋ \leq {I}_{ij} ( t , {t}^{′} ) \leq ⌊ \frac{Δ {Φ}_{ij} ( t , {t}^{′} )}{2 π} ⌋ + 1 \qquad Formula ( 3 )$$

Therefore, instead of Iᵢₕ(t,t′), the pseudo-vorticity matrix may be approximately constructed using a quantity obtained by appropriately discretizing

$$\frac{Δ {Φ}_{ij} ( t , {t}^{′} )}{2 π}$$

$$( such as ⌊ \frac{Δ {Φ}_{ij} ( t , {t}^{′} )}{2 π} + \frac{1}{2} ⌋ )$$

Here, |x| denotes the floor function.

Next, the synchronization graph generation unit 22 generates an undirected graph on the basis of the pseudo-vorticity matrix obtained as a result of the calculation by the pseudo-vorticity matrix calculation unit 21 (step S202 in FIG. 2). That is, on the basis of the pseudo-vorticity matrix, an undirected graph having a symmetric adjacency matrix A shown in Formula (4) is generated.

$$[ Math . 4 ]$$

$${A}_{ij} = \{ \begin{matrix}1 , & \vert {I}_{ij} ( t , {t}^{′} ) \vert \leq {c}_{s} , i \neq j \\ 0 , & otherwise\end{matrix} \qquad Formula ( 4 )$$

In the undirected graph shown in Formula (4), each vertex represents an oscillator, and when two vertices are connected by an edge, the two oscillators corresponding to those two points are synchronized (two-point synchronization). Since this undirected graph visually represents two-point synchronization within the system, it will hereinafter be referred to as the “synchronization graph.” Here, cₛ is a pseudo-vorticity threshold value for determining the presence or absence of two-point synchronization, and can take a value according to the detection mode. For example, cₛ=1 and cₛ=0 are necessary and sufficient conditions for satisfying −2π≤ΔΦᵢⱼ(t, t′)<2π. Therefore, when detecting all two-point synchronizations in which the phase difference obtained by time evolution is within 2π, cₛ is set to 1.

Next, the partial synchronization set detection unit 23 detects a subset family (equivalence class) corresponding to a group of oscillators that are partially synchronized in the synchronization graph generated by the synchronization graph generation unit 22 (step S203 in FIG. 2). That is, the partial synchronization set detection unit 23 detects a group of oscillators that are partially synchronized by detecting a clique in the synchronization graph. A clique in an undirected graph is a subset of the vertices such that there exists an edge connecting every two vertices in the subset. Therefore, a clique in a synchronization graph represents a partial synchronization that exists in an oscillator system, with all the oscillators in the clique being two-point synchronized. Therefore, if the vertices of the synchronization graph are divided into a plurality of cliques having no common portion, it can be seen that these cliques function as equivalence classes characterizing partial synchronization within the system.

Such a clique partition is not unique and there may be a plurality of possible partitions. For this reason, the partial synchronization set detection unit 23 of the present embodiment first obtains the largest partially synchronous clique in the oscillator system. This is known as the maximum clique problem, and since it is NP-hard, it is difficult to obtain an exact solution, but it is known that an approximate solution can be obtained relatively easily using numerical calculations. For example, after mapping to an Ising problem, a specific approximate solution can be obtained by using a numerical algorithm called a simulated annealing method. A method for obtaining such an approximate solution is described in, for example, NPL 3. However, there are known methods for obtaining a large number of approximate solutions to the Ising problem, and methods other than the simulated annealing method may be employed. Moreover, the maximum clique problem may be solved without going through the Ising problem.

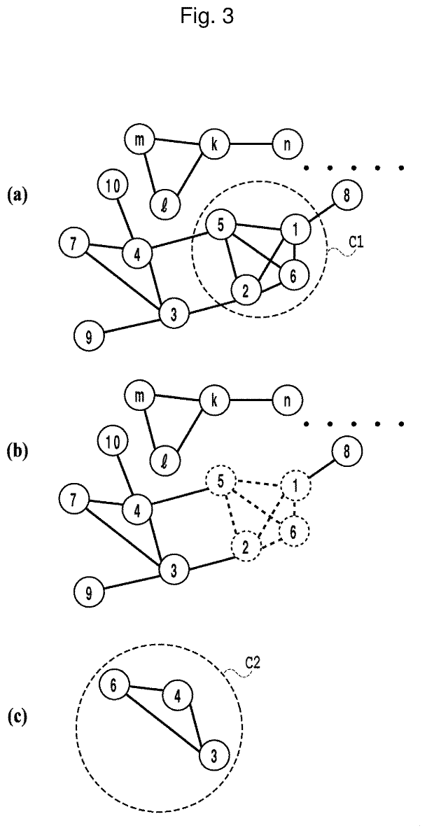

FIGS. 3(a), 3(b), and 3(c) are diagrams for schematically describing a clique partition process according to the present embodiment by solving a maximum clique problem. FIG. 3(a) shows a synchronization graph of oscillators 1 to 10, . . . , k to n, and so on. In FIG. 3(a), for the sake of simplicity of description and illustration, the number of vertices (oscillators) in each clique is shown as an example of a small number, such as three or four, and the number of cliques is also shown as an example of a small number, and it goes without saying that the actual number of vertices (oscillators) and the number of cliques to be partitioned are not limited to the example shown in FIG. 3(a). The synchronization graph shown in FIG. 3(a) includes the cliques {1, 2, 5, 6}, {3, 4, 7}, and {k, l, m}.

The detection unit 23 detects {1, 2, 5, 6}, whose maximum number is 4, as a clique c₁ in the synchronization graph shown in FIG. 3(a) by solving the maximum clique problem. Then, as shown in FIG. 3(b), the vertices included in the obtained clique c₁ and the edges connected to the vertices are removed from the synchronization graph (indicated by broken lines in FIG. 3(b)). Next, as shown in FIG. 3(c), in the synchronization graph consisting of the remaining vertices, the maximum number of cliques is detected and removed in the same manner as above. In the example shown in FIG. 3(b), a clique c₂ of {3, 4, 6}, whose maximum number is 3, is detected and removed. By repeating the same process, m cliques cⱼ (j=1, . . . , m) that partition the vertices (oscillators) are obtained. Each clique is numbered starting from 1 in the order in which it is found. Each clique cⱼ can be regarded as a subset (equivalence class) corresponding to a group of oscillators that are partially synchronized. In detecting the clique C₂, in addition to the clique {3, 4, 6}, there is also a clique {k, l, m} with a maximum number of 3. However, for example, by preferentially detecting the vertex (oscillator) with the smaller number assigned in the calculation, it is possible to deal with the case where cliques with the same maximum number exist.

Furthermore, partial synchronization of the oscillators can be expressed in an easy-to-understand manner by renumbering the oscillators in order of decreasing number of oscillators belonging to cliques (within the same clique, renumbering them in order of decreasing phase at a given time). In another embodiment, when partitioning a synchronization graph into cliques, the method that minimizes the size of a partition is obtained. This is the minimum clique cover problem, which is known to be NP-complete.

Next, the synchronization index calculation unit 24 calculates an index indicating the degree of synchronization of the entire system from the subset cᵢⱼ (j=1, . . . , m) representing partial synchronization and the pseudo-vorticity matrix I(t, t′) (step S204 in FIG. 2). As an index of the degree of synchronization, an index based on entropy and an index based on frequency can be calculated, and the synchronization index calculation unit 24 of the present embodiment can calculate either index.

First, an index based on entropy will be described. When the size of the set of a clique cⱼ detected by the partial synchronization set detection unit 23 is sⱼ, the inequality s1≥s2≥ . . . ≥sm is satisfied, and

$${\sum }_{i} {s}_{i} = n$$

is satisfied. Using this size, the discrete probability is defined by the following Formula (5).

$$[ Math . 5 ]$$

$${p}_{j} ≡ \frac{{s}_{j}}{n} , j = 1 , … , m \qquad Formula ( 5 )$$

This discrete probability represents the probability that oscillators, assumed to be equivalent, belong to the subset corresponding to the j-th partial synchronization. Therefore, the degree of synchronization of the entire system, including partial synchronization, can be associated with the non-uniformity of this probability. For example, when there is complete synchronization, all oscillators belong to one partial synchronization set, so that p₁=1. On the other hand, when all oscillators are two-point asynchronous, all oscillators belong to different cliques, so that p1=p2= . . . =pn=1/n. It is known that such non-uniformity of probability can be quantified as Shannon entropy, as shown in Formula (6). Formula (6) represents the index based on entropy generated by the synchronization index calculation unit 24.

$$[ Math . 6 ]$$

$${S}_{sync} ≡ - {\sum }_{j = 1}^{m} {p}_{j} log {p}_{j} \qquad Formula ( 6 )$$

From Formula (6), if all the oscillators are completely synchronized, S_{sync}=0, and if they are completely asynchronous, S_{sync}=logn. When S_{sync} falls within this range, it indicates that there is partial synchronization in the system. Since the entropy S_{sync} represents the degree of synchronization, it will hereinafter be referred to as “synchronization entropy.” In summary, synchronization entropy can be referred to as follows.
S_{sync}=0: All oscillators are synchronized.
S_{sync}=logn: All oscillators are asynchronous.
0<S_{sync}<logn: Some partial synchronization state is in place.
However, the present disclosure is not limited to using Shannon entropy to construct synchronization entropy. In general, the non-uniformity of probabilities can be quantified using any Schur-concave function. Shannon entropy is also a type of Schur-concave function. For example,

$${S}_{sync} ≡ 1 - max \vec{p} = 1 - \frac{{s}_{1}}{n}$$

can be used as another candidate example.
Since this is obtained only from s1, it is possible to eliminate the need to repeatedly solve the clique problem, and it can be used as a simple synchronization entropy.

As for an index based on frequency, which is another example of an index indicating the degree of synchronization, partial synchronization can also be quantified by how much different frequencies the oscillators in the system have. Therefore, the pseudo-vorticity matrix is used to calculate the characteristic frequency as shown in the following Formula (7).

$$[ Math . 7 ]$$

$$Δ f ≡ \frac{{\vert I ( t , {t}^{′} ) \vert}_{F}}{\sqrt{2} n Δ t} . \qquad Formula ( 7 )$$

In Formula (7), ∥(t, t′)|_{F} represents the Frobenius norm

$$\sqrt{{\sum }_{ij} {I}_{ij}^{2}}$$

of the pseudo-vorticity matrix.

The characteristic frequency thus defined represents a typical degree of dispersion of the frequency distribution of oscillators in the system. For example, the standard deviation of the frequencies of n independent oscillators approaches Δf if the measurement time is long enough. Therefore, Δf is referred to as the degree of non-uniformity of the frequency. If Δf is sufficiently smaller than the reciprocal of the measurement interval Δt, it can be considered that each oscillator has a similar frequency during measurement. On the other hand, if the degree of non-uniformity is larger than the reciprocal of the measurement interval Δt, it can be considered that there are oscillators with a plurality of frequencies in the system. For this reason, depending on whether ΔfΔt is greater than 1 or not, it can be determined whether the state of the system has one frequency or a plurality of frequencies. For this reason, Δ t obtained by Formula (7) will hereinafter also be referred to as the “frequency index of the degree of synchronization.”

As described above, in the present embodiment, it is possible to determine whether or not there is obvious partial synchronization in a system from the synchronization entropy and the non-uniformity of the frequency.

In particular, if the synchronization entropy and the non-uniformity of the frequency are used together and 0<S_{sync}<logn and ΔfΔt>1, it can be identified as a partial synchronization state in which a partial synchronization area and an asynchrony area are mixed with a large frequency difference.

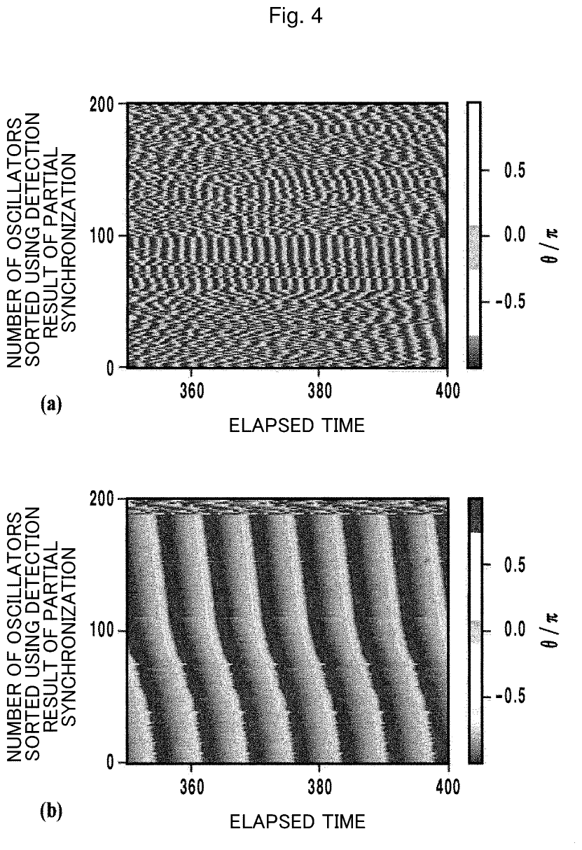

Next, an example of using the synchronization detection device and the synchronization detection method of the present embodiment described above will be described. FIGS. 4(a) and 4(b) are diagrams illustrating the results of numerical calculations simulating the time evolution of an oscillator system in which artificial neurons following the Fitzhugh-Nagumo model, a mathematical model that mimics the phenomenon of neuronal firing, are coupled in a small-world network. The pseudo-vorticity threshold value is set to cₛ=1. In both FIGS. 4(a) and 4(b), the horizontal axis indicates elapsed time, the left vertical axis indicates the number of oscillators sorted using the detection result of partial synchronization, and θ/π shown on the right vertical axis indicates the oscillation frequency of the oscillator. The density of the images shown in FIGS. 4(a) and 4(b) corresponds to the density of the bars indicating the frequency, and indicates the frequency at which the oscillator oscillates.

FIGS. 4(a) and 4(b) show the results using different model parameters. The results shown in FIGS. 4(a) and 4(b) both satisfy 0<S_{sync}<logn. From this, it can be confirmed that the oscillator systems shown in FIGS. 4(a) and 4(b) show partially synchronous time evolution in which the synchronization area and the asynchrony area are mixed. However, the state of the oscillator system shown in FIG. 4(a) and the state of the oscillator system shown in FIG. 4(b) differ in the degree of non-uniformity of the frequency. The state shown in FIG. 4(a) is ΔfΔt>>1, which is a state including partial synchronization with a large frequency difference. On the other hand, the state shown in FIG. 4(b) is ΔfΔt to 1, which is a partial synchronization state where the frequency difference is small. From these results, it was confirmed that the present embodiment can specifically detect partial synchronization areas and clarify the differences in their states.

A small-world network is a characteristic network that is commonly found in a variety of systems, including networks of movie actors co-starring, power line networks, neural networks of nematodes, and networks of neurons in the brain. The results shown in FIGS. 4(a) and 4(b) suggest that the synchronization detection device and the synchronization detection method of the present embodiment may be applicable to these various fields.

### REFERENCE SIGNS LIST

1 Synchronization detection system
10 Oscillator system
11 Phase information output unit
20 Synchronization detection device
21 Pseudo-vorticity matrix calculation unit
22 Synchronization graph generation unit
23 Partial synchronization set detection unit
24 Synchronization index calculation unit

1. A synchronization detection system comprising:
a phase information output unit that outputs time evolution information of phases from an oscillator system including a finite number of oscillators;
a pseudo-vorticity matrix calculation unit that calculates a matrix having elements each of which is a discretized value of a phase difference obtained by two of the oscillators by time evolution;
a synchronization graph generation unit that generates a synchronization graph that visualizes two-point synchronization with a graph representation;
a partial synchronization set detection unit that detects a plurality of subsets of the oscillators that have no common portion and are partially synchronized in a set of a finite number of the oscillators in the synchronization graph generated by the synchronization graph generation unit; and
a synchronization index calculation unit that generates an index characterizing partial synchronization of the oscillator system using a calculation result calculated by the pseudo-vorticity matrix calculation unit and a partial synchronization set detected by the partial synchronization set detection unit.

2. A synchronization detection device comprising:
a pseudo-vorticity matrix calculation unit that inputs time evolution information of phases from an oscillator system including a finite number of oscillators and calculates a matrix having elements each of which is a discretized value of a phase difference obtained by two of the oscillators by time evolution;
a synchronization graph generation unit that generates a synchronization graph that visualizes two-point synchronization with a graph representation;
a partial synchronization set detection unit that detects a plurality of subsets of the oscillators that have no common portion and are partially synchronized in a set of a finite number of the oscillators in the synchronization graph generated by the synchronization graph generation unit; and
a synchronization index calculation unit that generates an index characterizing partial synchronization of the oscillator system using a calculation result calculated by the pseudo-vorticity matrix calculation unit and a partial synchronization set detected by the partial synchronization set detection unit.

3. The synchronization detection device according to claim 2, wherein the synchronization index calculation unit generates at least one of an entropy index characterizing partial synchronization of the oscillator system and a frequency index characterizing the partial synchronization.

4. The synchronization detection device according to claim 2, wherein the pseudo-vorticity matrix calculation unit expresses partial synchronization occurring in the oscillator system as a matrix having elements each of which is a discretized value of a phase difference obtained by two of the oscillators by time evolution.

5. The synchronization detection device according to claim 2, wherein the synchronization graph generation unit generates the synchronization graph by visualizing two-point synchronization, for partial synchronization occurring in the oscillator system, with a graph representation.

6. The synchronization detection device according to claim 5, wherein the partial synchronization set detection unit detects and visualizes a partial synchronization set from the synchronization graph.

7. A synchronization detection method comprising:
a pseudo-vorticity matrix calculation step of inputting time evolution information of phases from an oscillator system including a finite number of oscillators and calculating a matrix having elements each of which is a discretized value of a phase difference obtained by two of the oscillators by time evolution;
a synchronization graph generation step of generating a synchronization graph that visualizes two-point synchronization with a graph representation;
a partial synchronization set detection step of detecting a plurality of subsets of the oscillators that have no common portion and are partially synchronized in a set of a finite number of the oscillators in the synchronization graph generated in the synchronization graph generation step; and
a synchronization index calculation step of generating an index characterizing partial synchronization of the oscillator system using a calculation result calculated in the pseudo-vorticity matrix calculation step and a partial synchronization set detected in the partial synchronization set detection step.
